(19) United States
(12) Patent Application Publication
(10) Pub. No.: US 2023/0058216 A1
(43) Pub. Date: Feb. 23, 2023

(54) A SELF-ALIGNING PREPARATION METHOD FOR A DRAIN END UNDERLAP REGION OF TUNNEL FIELD EFFECT TRANSISTOR

(71) Applicant: Peking University, Beijing (CN)

(72) Inventors: Qianqian Huang, Beijing (CN); Yiqing Li, Beijing (CN); Kaifeng Wang, Beijing (CN); Menghuan Yang, Beijing (CN); Zhixuan Wang, Beijing (CN); Le Ye, Beijing (CN); Yimao Cai, Beijing (CN); Ru Huang, Beijing (CN)

(21) Appl. No.: 17/636,980

(22) PCT Filed: Nov. 30, 2020
(86) PCT No.: PCT/CN2020/132725

§ 371 Date: Feb. 21, 2022

(30) Foreign Application Priority Data
May 13, 2020 (CN) 202010401204.1

(51) Int. Cl. H01L 29/66; H01L 21/768; H01L 21/28; H01L 21/8234; H01L 29/49

(52) U.S. Cl. CPC H01L 29/66507; H01L 21/76897; H01L 21/28052; H01L 21/823443; H01L 29/6659; H01L 29/4933

(57) ABSTRACT

A self-aligning preparation method for a drain underlap region in a tunnel field effect transistor: designing asymmetric side wall structures on two sides of the gate of a tunnel field effect transistor, the side of the gate closest to the source region being a thin side wall and the side of the gate closest to the drain region being a thick side wall; and using the source region thin side wall as a hard mask for implantation of the source region of the transistor and the drain region thick side wall as a hard mask for implantation of the drain region of the transistor. The present method effectively uses the thin side walls and thick side walls existing in standard CMOS processes to suppress the ambipolar effect of the tunnel field effect transistor without introducing special materials and special processes, and also optimizes the device variation characteristics. The present method ensures that the tunnel field effect transistor can be monolithically integrated with standard CMOS devices to implement more complex and diverse circuit functions.

### TECHNICAL FIELD

The present invention relates to the field of Field Effect Transistor (FET) devices and circuits in CMOS Ultra Large Scale Integrated Circuit (ULSI), and in particular, to the design and preparation of the drain underlap region of a tunnel field effect transistor (TFET).

### BACKGROUND OF THE INVENTION

With development of Integrated Circuits (ICs), the feature size of devices continues to decrease, the density of chip power consumption continues to increase, and the circuit power consumption has gradually become a key factor limiting the scaling down of ICs. An optimum method to reduce the power consumption of ICs is to reduce the power supply voltage. However, the sub-threshold slope of MOSFET is limited by thermal voltage, which shall not be lower than 60 mV/dec at room temperature. The leakage current of devices will rise exponentially following further reduction of the power supply voltage while maintaining certain drive capability, causing additional power consumption costs. The impact is particularly severe after the devices enter the nanoscale. The tunnel field effect transistor (TFET) uses the band-to-band tunnelling mechanism to solve the limitation of thermal voltage, which can achieve ultra-steep sub-threshold slope and high on/off ratio of current under low voltage, considered as to the most promising low-power device possible to replace MOSFET in future.

As a gate-controlled reverse-biased P-I-N junction, TFET has characteristics such as low off-state current, steep sub-threshold slope and compatible with traditional CMOS processes. However, considering the unique structure and electrical characteristics of TFET device, the preparation process of TFET needs to be optimized based on traditional CMOS processes. One characteristic that has major impact on the electrical performance of TFET device is the ambipolar effect, which indicates the additional tunneling current at drain side when reverse-biased gate voltage is applied to the device. And this additional tunneling current is called additional ambipolar current, which may cause increased leakage current of the device and decreased on/off ratio. The traditional method of suppressing this ambipolar effect is to shift the drain implantation mask, so that a part of the intrinsic region is reserved between the channel and the drain region, which is called the drain underlap region. However, the ion implantation heavily depends on the lithography accuracy when using this method, introducing additional variation source, which is not conducive to device consistency, and affects the mass production of TFET. Moreover, this method is also not conducive to subsequent metal silicide process, therefore affecting the contact of the device, and not conducive to the use of dopant segregation and/or other techniques. Therefore, it has become an urgent problem in the design of conventional TFET devices on how to self-align the drain underlap region to optimize the ambipolar effect while maintaining device consistency.

### SUMMARY OF THE INVENTION

The present invention provides a self-aligning preparation method of drain underlap region of tunnel field effect transistor. The present method effectively uses the existing parts in standard CMOS processes to effectively suppress the ambipolar effect of the device while maintaining the device consistency, and is conducive to the introduction and usage of advanced processes such as metal silicide.

A self-aligning preparation method for a drain end underlap region of a tunnel field effect transistor is disclosed. The method includes the one or more of the following steps:

Step 1) preparing a semiconductor substrate and isolating an active area in a semiconductor substrate;

Step 2) growing a gate dielectric material, and then growing the gate material on the gate dielectric material;

Step 3) forming a gate pattern by photolithography and etching;

Step 4) growing thin side walls on the sides of the gate pattern.

Step 5) continuing to grow thick side walls on the sides of the gate pattern;

Step 6) removing the thick side wall on a side of the gate closest to a source region, and reserving the thin side wall on the side of the gate closest to the source region;

Step 7) using photoresist and the thick side wall on a side of the gate closest to a drain source region as a mask for implantation of the drain region of the tunnel field effect transistor;

Step 8) using photoresist and the thick side wall on a side of the gate closest to a source region as a mask for implantation of the source region of the tunnel field effect transistor; and

Step 9) high-temperature annealing to activate impurities, and then entering the back-end-of-line (BEOL) which is the same as CMOS, including depositing passivation layers, opening contact holes, and metallization, to obtain a tunnel field effect transistor (TFET) with a self-aligned drain underlap region.

In the above preparation method, the semiconductor substrate material in Step 1) is selected from Si, Ge, SiGe, GaAs or other binary or ternary compound semiconductors from II-VI, III-V and IV-IV groups, silicon-on-insulator (SOI) or germanium-on-insulator (GOI).

In the above preparation method, the gate dielectric material in Step 2) is selected from SiO₂, Si₃N₄ or high-K gate dielectric materials.

In the above preparation method, the method for growing the gate dielectric material in Step 2) is selected from one of the following methods: conventional thermal oxidation, nitrogen-doped thermal oxidation, chemical vapor deposition (CVD), and physical vapor deposition (PVD).

In the above preparation method, the gate material in Step 2) is selected from doped polysilicon, metal cobalt, nickel, or other metals or metal silicides.

In the above preparation method, the thin side wall in Step 4) and the thick side wall in Step 5) are made of the same or different materials.

In the above preparation method, the side wall material is selected from one or more laminated combinations of silicon oxide, silicon nitride, or silicon carbide.

In the above preparation method, the thickness of the thin side wall in Step 4) is about 5 nm-10 nm.

In the above preparation method, the thickness of the thick side wall in Step 5) is about 40 nm-60 nm.

In the above preparation method, if there is no etch stop layer between the thick side wall and the thin side wall in Step 6), the side wall closest to the source region can be completely removed and grow the thin side wall again.

Compared with the prior technology, the presently disclosed method includes one or more the following advantages:

The present invention proposes a method designing asymmetric side wall structures on two sides of the gate of a tunnel field effect transistor, the side of the gate closest to the source being a thin side wall and the side of the gate closest to the drain being a thick side wall. The present invention effectively uses the thin side walls and thick side walls existing in standard CMOS processes, using the thin side wall on source side as a hard mask for implantation of the source region of the transistor and the thick side wall of the drain side as a hard mask for implantation of the drain region of the transistor, to ensure that the TFET can be monolithically integrated with standard CMOS to implement more complex and diverse circuit functions without introducing special materials and special processes.

The present invention can effectively suppress the ambipolar effect and does not introduce new non-ideal effects due to processes such as metal silicide. Moreover, scaling down with advanced processes can be achieved.

The thickness of the side wall in the present invention can be controlled via the growth and etching time and rate of the side wall material, without considering the engraving deviation in the photolithography process, and there is good consistency between the wafers, dies, and devices. Thus, the self-aligning source-drain implantation using the present invention can greatly optimize the device variation characteristics, ensuring that the device has good consistency, which is beneficial to the mass production of TFET.

### BRIEF DESCRIPTION OF THE DRAWINGS

FIG. 1 illustrates a schematic cross-section of the complete structure of a tunnel field effect transistor after back-end-of-line (BEOL) process according to some embodiments of the present invention;

FIG. 2 illustrates a schematic cross-section after forming STI isolation on the semiconductor substrate according to one embodiment;

FIG. 3 illustrates a schematic cross-section after growing the gate dielectric and the gate materials and completing the gate pattern according to one embodiment;

FIG. 4 illustrates a schematic cross-section after growing the thin side wall according to one embodiment;

FIG. 5 illustrates a schematic cross-section after growing the thick side wall according to one embodiment;

FIG. 6 illustrates a schematic cross-section after removing the source region thick side wall according to one embodiment; and

FIG. 7 illustrates a schematic cross-section after ion implantation of the source/drain according to one embodiment;

### Where:

| | |
|---|---|
| 1—Substrate; | 2—Shallow Trench Isolation (STI) |
| 3—Gate dielectric layer; | 4—Gate, |
| 5—Thin side wall; | 6—Thick side wall; |
| 7—Source region; | 8—Drain region; |
| 9—Passivation layer of | 10—Metal of back-end-of-line. |
| back-end-of-line; | |

### DETAILED DESCRIPTION OF THE INVENTION

The present invention will become apparent from the following detailed description of embodiments. It is to be noted that the above contents are further detailed description of the present invention in connection with the disclosed embodiments. The invention is not limited to the embodiments referred to, but may be varied and modified by those skilled in the field without departing from the conception and scope of the present invention. The claimed scope of the present invention should be defined by the scope of the claims.

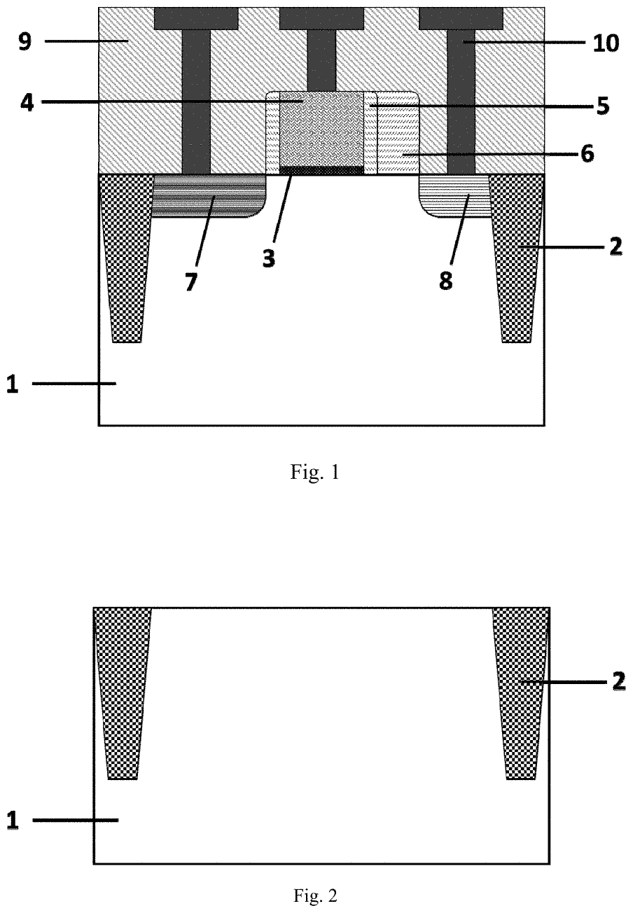

A specific embodiment of the preparation method in the present invention comprises the steps in FIGS. 1-7:

1. Thermally oxidizing a silicon dioxide layer on a bulk silicon substrate (item 1) initially with light doping concentration and (100) crystal orientation, with thickness of about 10 nm, and depositing a silicon nitride layer with thickness of about 100 nm; then etching the Shallow Trench Isolation (STI) region, depositing isolation material to fill deep holes and then Chemical Mechanical Polishing (CMP); preparing the active region STI (item 2) by Shallow Trench Isolation (STI) and then remove the silicon nitride by wet etching, as illustrated in FIG. 2.

2. Performing well implantation with phosphorus, the ion implantation dose is 1e13 cm⁻², and the ion implantation energy is 340 keV.

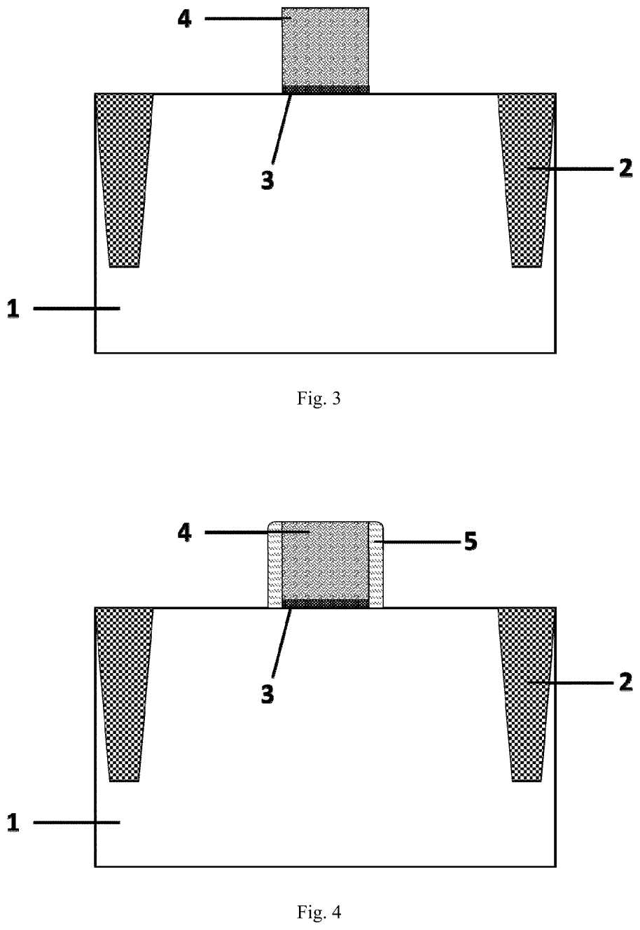

3. Bleaching the initially grown silicon dioxide on the surface, and then thermally oxidizing a gate dielectric layer (item 3). The above gate dielectric layer (item 3) is SiO₂ with thickness of about 1.8 nm; depositing the gate material of doped polysilicon layer with thickness of about 100 nm. Pre-implanting polysilicon with phosphorus, wherein the implantation dose is 4e15 cm⁻², and the implantation energy is 6 keV. Patterning the gate pattern through photolithography and etching the gate material and the gate dielectric layer (item 3) until to bulk silicon substrate (item 1), as illustrated in FIG. 3.

4. Isotropically depositing and growing 8.5 nm silicon nitride, then anisotropically etching 8.5 nm silicon nitride to form the thin side wall (item 5), and performing thermal annealing at 800° C. for 30 minutes, as illustrated in FIG. 4.

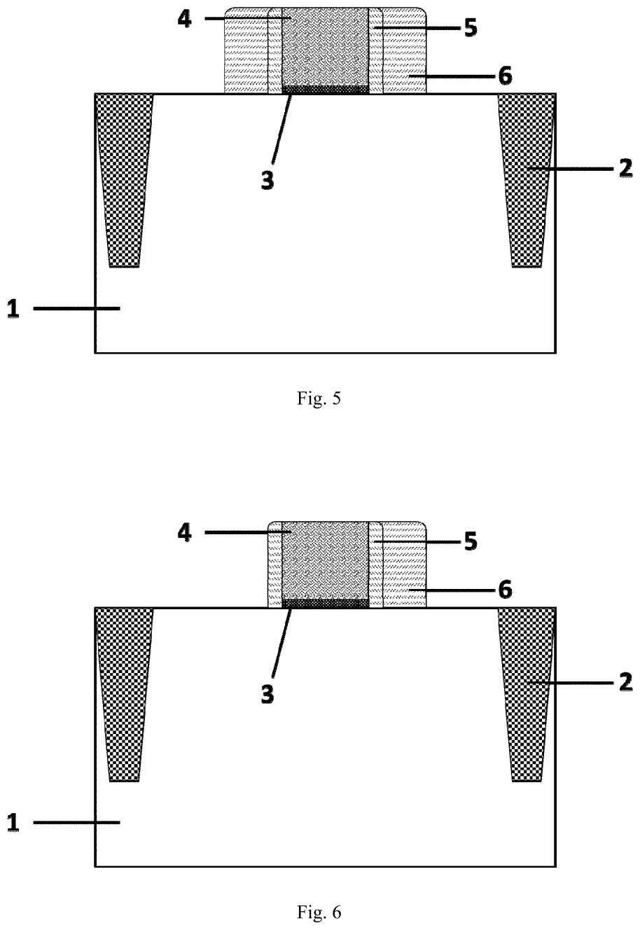

5. Isotropically depositing and growing 9 nm silicon dioxide, followed by isotropic deposition and growth of 42 nm silicon nitride. Anisotropically etching 42 nm silicon nitride, followed by 9 nm silicon dioxide to form the thick side wall (item 6), as illustrated in FIG. 5.

6. Depositing 15 nm thick layer of silicon dioxide, exposing the source region by photolithography, which protects the drain end gate region and the thick side wall by photoresist. Isotropic over-etching 15 nm silicon dioxide that is not protected by photoresist. Removing the photoresist. Isotropic over-etching 42 nm silicon nitride. Isotropic over-etching 9 nm silicon dioxide. At this time, the source end thick side wall has been removed, as illustrated in FIG. 6.

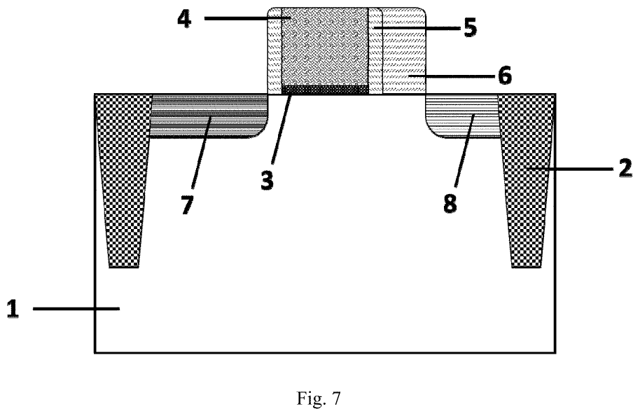

7. Performing source and drain implantation respectively, and one edge of the implantation mask is located on the center line of gate (item 4). The implanted ion in source region (item 7) is BF₂⁺, the implantation dose is 2e15 cm⁻², and the implantation energy is 5 keV; the implanted ion in drain region (item 8) is As, the implantation dose is 2e15 cm⁻², and the implantation energy is 5 keV. Performing rapid thermal annealing to activate the impurities, as illustrated in FIG. 7.

8. Growing the passivation layer (item 9) and the metal (item 10) of back-end-of-line (BEOL) using the same process as CMOS BEOL to obtain a tunnel field effect transistor with the structure shown in FIG. 1.

Although the present invention has been disclosed as said in preferred embodiments, it is not limited to the embodiments referred to. The technical scheme of the present invention may be varied and modified by those skilled in the field without departing from the conception and the scope of the present invention using the present method and technical content disclosed as said, or it may be modified into an equivalent embodiment of equivalent changes. Thus, any simple modifications and equivalent changes made to the embodiments based on the technical essence of the present invention without departing from the technical scheme of the present invention are still within the protection scope of the technical scheme of the present invention.

What is claimed is:

1. A method for preparing a drain end underlap region in a tunnel field effect transistor using self-alignment, comprising:
1) isolating an active region in a semiconductor substrate;
2) growing a gate dielectric material, and growing a gate material on the gate dielectric material;
3) forming a gate pattern using photolithography and etching;
4) growing thin side walls on sides of the gate pattern;
5) growing thick side walls on the thin side walls on the sides of the gate pattern;
6) removing the thick side wall on a side of the gate closest to a source region, while keeping the thin side wall on the side of the gate closest to the source region;
7) using photoresist and the thick side wall on a side of the gate closest to a drain source region as a mask for implantation of the drain region of the tunnel field effect transistor;
8) using photoresist and the thick side wall on a side of the gate closest to a source region as a mask for implantation of the source region of the tunnel field effect transistor; and
9) high-temperature annealing to activate impurities to form the tunnel field effect transistor with a self-aligned drain underlap region.

2. The method of claim 1, wherein the semiconductor substrate includes a material selected from Si, Ge, SiGe, GaAs, or binary or ternary compound semiconductors from II-VI, III-V and IV-IV group, silicon-on-insulator (SOI) or germanium-on-insulator (GOI).

3. The method of claim 1, wherein the gate dielectric material comprises SiO₂, Si₃N₄, or a high-K gate dielectric material.

4. The method of claim 1, wherein growing the gate dielectric material in step 2) comprises one or more of: conventional thermal oxidation, nitrogen-doped thermal oxidation, chemical vapor deposition (CVD), or physical vapor deposition (PVD).

5. The method of claim 1, wherein the gate material comprises doped polysilicon, metal cobalt, nickel, and other metals, or metal silicides.

6. The method of claim 1, wherein the thin side walls and the thick side walls are made of same or different side wall materials.

7. The method of claim 6, wherein the side wall material comprises one or more laminated combinations of silicon oxide, silicon nitride, or silicon carbide.

8. The method of claim 1, wherein the thin side walls have a thickness of 5 nm-10 nm.

9. The method of claim 1, wherein the thick side walls have a thickness of 40 nm-60 nm.

10. The method of claim 1, wherein if there is no etch stop layer between the thick side wall and the thin side wall in step 6), wherein step 6) further comprises:
removing both the thick side wall and the thin side wall closest to the source region; and
forming a second thin side wall close to the source region.
